(19) United States
(12) Patent Application Publication
(10) Pub. No.: US 2022/0390840 A1
(43) Pub. Date: Dec. 8, 2022

(54) Light-Enhanced Ozone Wafer Processing System and Method of Use

(71) Applicant: MKS Instruments, Inc., Andover, MA (US)

(72) Inventors: Jens Fittkau, Andover, MA (US); Christiane Le Tiec, Andover, MA (US); Curt Rettig, Andover, MA (US); Dirk Nolte, Andover, MA (US); Kay Mittler, Andover, MA (US); Carsten Becher, Andover, MA (US)

(21) Appl. No.: 17/830,232

(22) Filed: Jun. 1, 2022

Related U.S. Application Data
(60) Provisional application No. 63/196,472, filed on Jun. 3, 2021.

(51) Int. Cl. G03F 7/004; G03F 7/20

(52) U.S. Cl. CPC G03F 7/0043; G03F 7/707; G03F 7/2004

(57) ABSTRACT

A light-enhanced wafer processing system disclosed herein which includes a rotatable chuck configured to support and selectively rotate at least one wafer, at least one dispenser body configured to selectively flow at least one photolytic material onto a surface of the wafer, and at least one optical radiation source may be configured to provide optical radiation to at least a portion of the wafer having photolytic material applied thereto, wherein the optical radiation is configured to result in the formation of optically-induced radicals having enhanced reactivity with at least one material applied to the wafer.

### CROSS REFERENCE TO RELATED APPLICATIONS

The present patent application claims priority to U.S. Provisional Patent Application Ser. No. 63/196,472, filed on Jun. 3, 2021, entitled “Light-Enhanced Ozone Wafer Processing System and Method of Use,” the entire contents of which are incorporated by reference herein.

### BACKGROUND

During the semiconductor manufacturing process multiple layers of photoresist and other materials may be sequentially applied to a substrate in a desired pattern. Thereafter, the coated substrate may be exposed to light at a specific wavelength thereby resulting in a pattern being transferred to the substrate. The sequence of steps may be repeated multiple times to build up multiple layers of a desired patterned circuitry. Thereafter, the photoresist must be removed from the wafer to reveal the desired pattern formed on the wafer.

Presently, photoresist removal processes commonly use of sulfuric acid and hydrogen peroxide (hereinafter SPM) to remove the photoresist once the pattern is formed on the wafer. For example, FIG. 1 shows an example of a typical photoresist removal process utilized in semiconductor manufacturing. As shown, the prior art photoresist removal process 1 includes the steps of loading a wafer to be processes onto a rotating wafer chuck and rotating the chuck having the wafer positioned thereon (reference number 3). Thereafter, a flow of SPM is initiated thereby coating a photoresist-coated surface of the wafer (reference number 5). The repeated application of photoresist to the wafer and additional processing forms a desired pattern of the wafer surface. Thereafter, the photoresist may be removed from the wafer surface (reference number 7) using, for example, an oxidation process and the flow of SPM discontinued (reference number 9). Thereafter, the repeated applications of SPM to the rotating wafer and repeated rinsing with ultrapure water (UPW) results in the to remove residual materials (reference number 11). In addition, the wafer may be dried or permitted to dry (reference number 13) before the processed wafer may be removed from the wafer chuck (reference number 15).

While the present SPM-based photoresist process has proven somewhat useful, a number of shortcomings have been identified. For example, SPM-based processing is costly because of storage, heating and limited chemistry lifetime. Further, viscous SPM may be difficult to completely remove from the surface of the wafer and requires extensive rinsing. Further, hygroscopic sulfur residues on the surface of the wafer can absorb moisture thereby creating particulate defects on the surface. In addition, the implanted photoresist may form or assist in forming a de-hydrogenated hard crust on the surface of the wafer during ion bombardment. Efficient removal of the de-hydrogenated hard crust has been problematic.

In light of the forgoing, there is an ongoing need for an alternate method of effectively and efficiently removing photoresist from wafer surface during processing.

### SUMMARY

The present application disclosed various embodiments of a light-enhance wafer processing system. More specifically, the light-enhanced wafer processing system disclosed herein enables the quick and efficient removal of one or more materials from a surface of a wafer or other substrate. While the system described herein may be configured for the removal of photoresist from a semiconductor wafer during wafer processing, the system may be used to removal any variety of materials from a wafer or similar substate. In one embodiment, the light-enhanced wafer processing system utilizes at least one photolytic material which, when irradiated with optical radiation at a selected wavelength and power, results in the formation of highly reactive radicals on the surface of the wafer being processed. The generated radicals may be employed to quickly and efficiently strip or otherwise selectively remove materials, such as photoresist or other materials, from the surface of the wafer being processed.

In one embodiment, the light-enhanced wafer processing system disclosed herein includes a processing body having a rotatable chuck configured to support and selectively rotate at least one wafer. At least one processing head, in communication with at least one source of at least one photolytic material, may be positioned proximate to the wafer positioned on the rotatable chuck. The processing head may be configured to selectively flow the photolytic material onto a surface of the wafer. Thereafter, at least one optical radiation source may be configured to provide optical radiation to at least a portion of the wafer having photolytic material applied thereto. The optical radiation is configured to result in the formation of optically-induced radicals having enhanced reactivity with at least one material applied to the wafer.

In another embodiment, the present application discloses a light-enhanced wafer processing system which includes a processing body having a rotatable chuck configured to support and selectively rotate at least one wafer. At least one processing head may be positioned proximate to the wafer supported by the rotatable chuck. The processing head may include at least one dispenser body in communication with at least one source of at least one photolytic material. The dispenser body may be configured to selectively flow at least one photolytic material onto a surface of the wafer. At least one optical radiation source may be configured to provide optical radiation to at least a portion of the wafer having photolytic material applied thereto. During use, the optical radiation is configured to result in the formation of optically-induced radicals having enhanced reactivity with at least one material applied to the wafer.

In yet another embodiment, the present application is directed to a light-enhanced wafer processing system. More specifically, the light-enhanced wafer processing system disclosed herein includes a rotatable chuck configured to support and selectively rotate at least one wafer. At least one dispenser body may be configured to selectively flow at least one photolytic material onto a surface of the wafer. In addition, at least one optical radiation source may be configured to provide optical radiation to at least a portion of the wafer having photolytic material applied thereto, wherein the optical radiation is configured to result in the formation of optically-induced radicals having enhanced reactivity with at least one material applied to the wafer.

Other features and advantages of the light-enhanced wafer processing system as described herein will become more apparent from consideration of the following detailed description.

### BRIEF DESCRIPTION OF THE DRAWINGS

The drawings disclose illustrative embodiments and are not intended to set forth all embodiments of the light-enhanced wafer processing system. Details that may be apparent or unnecessary may be omitted to save space or for more effective illustration. Conversely, some embodiments may be practiced without all the details disclosed with regard to the specific embodiments described herein. When the same referenced numbers appear in different drawings, the referenced numbers refer to same or similar components or steps. The novel aspects of the light-enhanced wafer processing system will be more apparent from consideration of the following figures, wherein:

FIG. 1 shows a flowchart of an exemplary photoresist removal process utilized in semiconductor manufacturing to remove photoresist from the surface of a semiconductor wafer during wafer processing;

FIG. 2 shows a flowchart of an embodiment of a photoresist removal process utilizing a light-enhanced processing system to remove photoresist from the surface of a semiconductor wafer during wafer processing;

FIG. 3 shows a schematic diagram of an embodiment of a light-enhanced processing system for use in selectively removing one or more materials from a surface of a wafer during processing;

FIG. 4 shows an elevated perspective view of an embodiment of a light-enhanced processing system for use in selectively removing one or more materials from a surface of a wafer during processing;

FIG. 5 shows a side cross-sectional view of an embodiment of a light-enhanced processing system for use in selectively removing one or more materials from a surface of a wafer during processing;

FIG. 6 shows an elevated perspective view of another embodiment of a light-enhanced processing system for use in selectively removing one or more materials from a surface of a wafer during processing;

FIG. 7 shows side cross-sectional view of the embodiment of the light-enhanced processing system of FIG. 6 having a dispenser body retracted from the wafer positioned on a rotatable chuck;

FIG. 8 shows side cross-sectional view of another embodiment of a light-enhanced processing system of FIG. 6 wherein the dispenser includes at least one optical radiation source positioned therein;

FIG. 9 shows side cross-sectional of the embodiment of the light-enhanced processing system of FIG. 6 having the dispenser body extended to the wafer positioned on a rotatable chuck;

FIG. 10 shows side cross-sectional of the embodiment of the light-enhanced processing system of FIG. 6 wherein the dispenser body extended to the wafer positioned on a rotatable chuck;

FIG. 11 shows an elevated perspective view of another embodiment of a light-enhanced wafer processing system wherein the wafer processing system includes an optical radiation scanning head;

FIG. 12 shows an elevated perspective view of an embodiment of a dispenser body for use with the embodiment of the light-enhanced wafer processing system shown in FIG. 11;

FIG. 13 shows an elevated perspective view of another embodiment of a dispenser body for use with the embodiment of the light-enhanced wafer processing system shown in FIG. 11, the dispenser body having an optical radiation source therein;

FIG. 14 shows a top view of an embodiment of the dispenser body shown in FIG. 12 for use with a light-enhanced wafer processing system;

FIG. 15 shows a top view of an embodiment of the dispenser body shown in FIG. 13 for use with a light-enhanced wafer processing system wherein the dispenser body includes at least one optical radiation source therein;

FIG. 16 shows a side view of another embodiment of a light-enhanced wafer processing system;

FIG. 17 shows an elevated perspective view of another embodiment of a light-enhanced wafer processing system; and

FIG. 18 shows a cross-sectional view of the embodiment of a light-enhanced wafer processing system shown in FIG. 17.

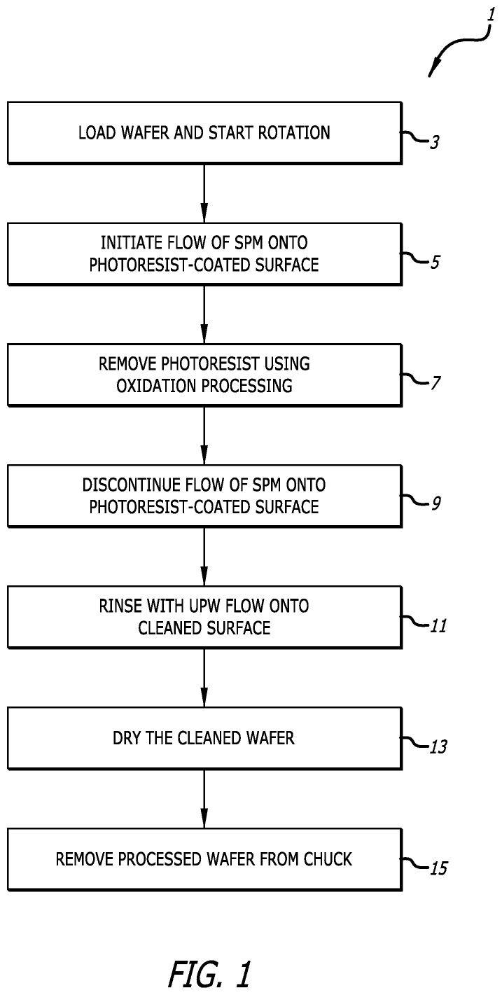

### DETAILED DESCRIPTION

Exemplary embodiments are described below with reference to the accompanying drawings. Unless otherwise expressly stated, in the drawings the sizes, positions, etc., of components, features, elements, etc., as well as any distances therebetween, are not necessarily to scale, and may be disproportionate and/or exaggerated for clarity.

The terminology used herein is for the purpose of describing particular example embodiments only and is not intended to be limiting. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first mirror” and similarly, another node could be termed a “second mirror”, or vice versa.

Unless indicated otherwise, the term “about,” “thereabout,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

Many of the embodiments described in the following description share common components, device, and/or elements. Like named components and elements refer to like named elements throughout. For example, all the embodiments described in the following detailed description disclose utilizing ozonated deionized water as a photolytic material to remove unwanted material from a substrate. Of course, those skilled in the art will appreciate that any variety of materials in any fluid or solid form, may be used to remove material from the substrate. For example, gaseous ozone may be used. Further, the various embodiments disclosed herein specifically discuss removing photoresist from a semiconductor substrate. However, it should be appreciated that any variety of materials may be removed from any variety of substrates using the various embodiments using the systems and methods disclosed herein. Thus, the same or similar named components or features may be described with reference to other drawings even if they are neither mentioned nor described in the corresponding drawing. Also, even elements that are not denoted by reference numbers may be described with reference to other drawings.

Many different forms and embodiments are possible without deviating from the spirit and teachings of this disclosure and so this disclosure should not be construed as limited to the example embodiments set forth herein. Rather, these example embodiments are provided so that this disclosure will be thorough and complete, and will convey the scope of the disclosure to those skilled in the art.

The present application discloses various systems and methods for efficiently removing photoresist or similar materials from a substrate. In one particular embodiment, the substrate comprises a semiconductor wafer, although those skilled in the art will appreciate that the systems and methods disclosed herein may be used to remove photoresist or similar materials from any variety of substrates. Unlike prior art photoresist removal systems and processes which relied primarily on SPM as a photoresist removal media, the various embodiments disclosed herein utilize ozone and light to remove one or more materials from at least one surface of a semiconductor wafer. Optionally, any variety of photo-disassociative materials may be used in place of or in combination with ozone. Further, in one embodiment, the one or more laser systems may be used to provide optical radiation/light to the ozone or other photolytic materials during wafer during processing.

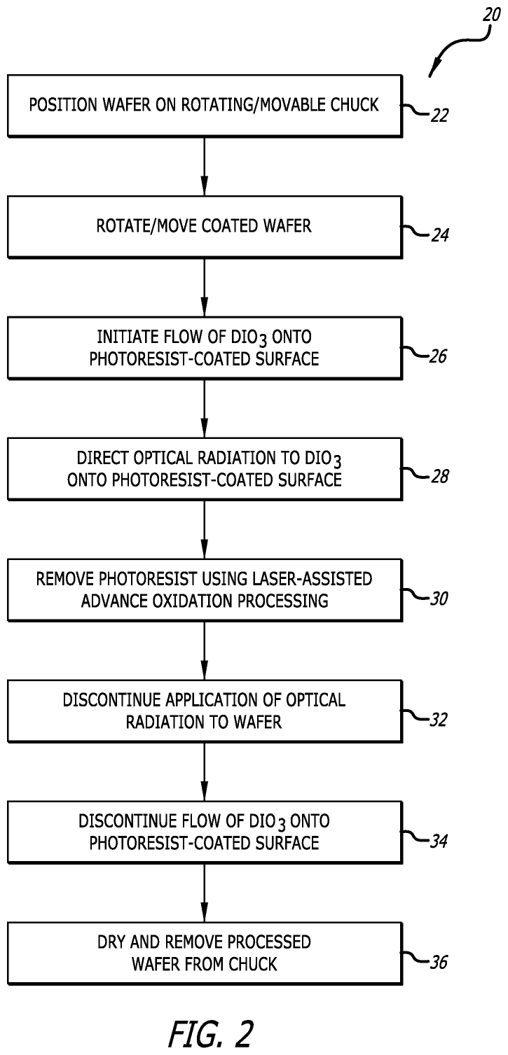

FIG. 2 shows a flowchart of a novel method of processing a substrate. More specifically, FIG. 2 describes a method of removing photoresist from a coated wafer substrate, but those skilled in the art will appreciate that any variety of materials may be removed from any variety of substrates using the described method. As shown, the processing method 20 includes positioning at least one substrate or wafer on a support or chuck (See FIG. 2, ref. no. 22). In the illustrated embodiment the chuck supporting the wafer may be controllably rotated (See FIG. 2, ref. no. 24), although those skilled in the art will appreciate that the chuck need not be rotated. Rather, the chuck may be linearly movable thereby permitting linear processing of substrates. Thereafter, at least one photolytic material or solution may be selectively applied to the wafer positioned on the chuck (See FIG. 2, ref. no. 26). In one embodiment, the photolytic materials comprise ozonated deionized water (hereinafter DIO3) or gaseous ozone (hereinafter O3), although those skilled in the art will appreciate that any variety of photolytic or photoreactive materials, solutions, or compounds may be used. In one embodiment, the DIO3 applied to the wafer surface has a concentration of about 1 ppm to about 600 ppm, although those skilled in the art will appreciate the DIO3 may have any desired concentration. For example, in one embodiment, the DIO3 applied to the wafer surface has a concentration of about 30 ppm to about 300 ppm. Optionally, the DIO3 may include dissolved carbon dioxide or other compounds or materials therein. For example, the dissolved carbon dioxide or other compound may be configured to stabilize the DIO3 or enhance reactivity of the DIO3. Those skilled in the art will appreciate that the dissolved carbon dioxide or other compounds may be used for any number of purposes. For example, in another embodiment, gaseous ozone (hereinafter O3) may be used instead of or in combination with DIO3. For example, 03 having a concentration range is from 0.25 g/Nm³ to about 2500 g/Nm³ may be used. In one specific embodiment, O3 having a concentration range from about 1 g/Nm³ to about 600 g/Nm³ may be used, although those skilled in the art will appreciate that any variety of O3 concentrations may be used. Optionally, any variety of alternate photolytic materials at any variety of concentration may be used. In one embodiment, the flow of photolytic materials onto the surface of the wafer comprises a turbulent flow, although a laminar flow may also use used.

Referring again to FIG. 2, optical radiation may be selectively applied to at least a portion of the wafer having DIO3 or O3 applied thereto (See FIG. 2, ref. no. 28). In one embodiment, the optical radiation or light may have a wavelength from about 100 nm to about 1000 nm. In another embodiment, the optical radiation has a wavelength of about 200 nm to about 400 nm. Optionally, the optical radiation may have a wavelength of about 230 nm to about 275 nm. In a specific embodiment, the optical radiation has a wavelength of about 246 nm to about 266 nm. Those skilled in the art will appreciate that the wavelength of the optical radiation may be determined by a number of factors, including, for example, type of photolytic material used, reactivity of the material being removed from the substrate, and the like. Similarly, in one embodiment, the optical radiation has a power from about 1 mW to about 100 W. In one specific embodiment, the power is from about 1 W to about 20 W. Optionally, the power may be about 8 W, although any power may be used. In one embodiment, the optical signal comprises a pulsed signal although those skilled in the art will appreciate that a continuous wave signal may be used. During use, the application of the optical radiation triggers the formation of optically-induced radicals having enhanced reactivity through ozone decay. As a result, the presence of ozone radicals fuels a chain reaction in close proximity to the photoresist on the wafer, which reacts with and strips photoresist molecules from the wafer surface (See FIG. 2, ref. no. 30).

As shown in FIG. 2, the application of optical radiation may be discontinued once a portion of or all photoresist has been removed from the substrate surface (See FIG. 2, ref. no. 32). Similarly, the flow of photolytic material onto the surface of the substrate may be halted (see FIG. 2, ref. no. 34). The substrate may be subjected to repeated applications of photolytic material and optical radiation to ensure essentially all desired materials are removed from the substrate. Once completed, the substrate may be dried and remove from the chuck (See FIG. 2, ref. no. 36).

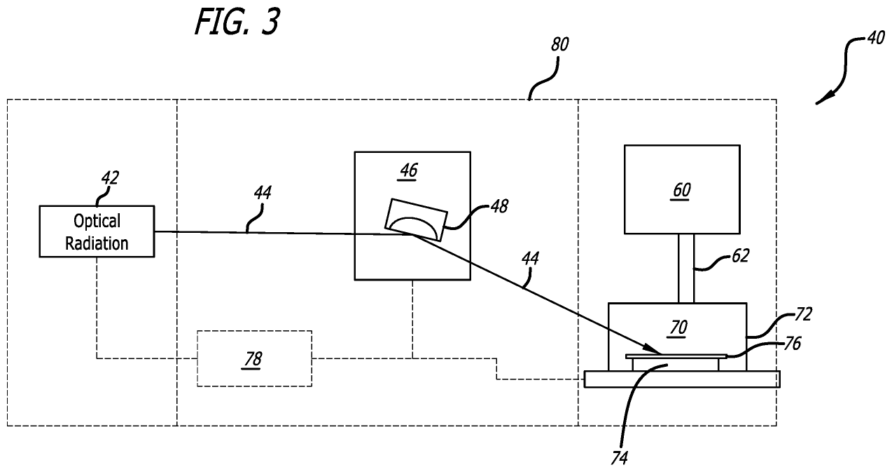

FIG. 3 shows a diagram of an embodiment of a light-enhance ozone wafer processing system. As shown, the processing system 40 includes at least one optical radiation source 42. In one embodiment, the optical radiation source 42 comprises at least one laser device. For example, optical radiation source 42 may comprise diode pumped solid-state laser system configured to output at least one optical signal 44. In one embodiment, the optical signal 44 comprises a pulsed signal although those skilled in the art will appreciate that the optical signal 44 may comprise a continuous wave signal. Further, as stated above, the optical radiation source 42 may be configured to output at least one optical signal 44 having a wavelength from about 100 nm to about 1000 nm. In a more specific embodiment, the optical signal 44 has a wavelength from about 250 nm to about 275 nm.

Referring again to FIG. 3, the optical signal 44 is directed to at least one beam control system 46 configured to controllably direct the optical signal 44 to at least one substrate 76 positioned within the substrate processing system 70. In the illustrated embodiment, the beam control system 46 comprises at least one scanning mirror or similar beam steering device 48 therein. Optionally, any variety of optical elements may be used to form the various components of the beam control system 46, including, without limitations, mirrors, lenses, filters, apertures, irises, sensors, motors, optical mounts, controllers, and the like.

Referring again to FIG. 3, the substrate processing system 70 includes at least one chuck or substrate support 74 therein. The chuck 74 may be configured to position the substrate 76 at a desired location within the substrate processing system 70. In one embodiment, the chuck 74 is configured to be selectively rotatable. In another embodiment, the chuck 74 may be linearly moveable. Optionally, the chuck 74 may be configured to be moveable along any desired plane.

As shown in FIG. 3, at least one photolytic material supply source 60 may be in fluid communication with the substrate processing system 70 via at least supply conduit 62. The photolytic material supply source 60 may be configured to selectively supply photolytic material to the substrate processing system 70. In addition, at least one of the optical radiation source 42, beam control system 46, photolytic material supply source 60, and substrate processing system 70 may be in communication with at least one processor and control system 78. The control system 78 may be configured to vary any number of performance characteristics of the optical radiation source 42, beam control system 46 photolytic material supply source 60, and substrate processing system 70. For example, the control system 78 may vary the repetition rate and/or power of the optical radiation source 42, varying the scan rate of the beam control system 46, initiate/cease the flow of photolytic material to the substrate processing system 70 from the photolytic material supply system 60, the rotation rate/position of the chuck 74 and the like. Optionally, one or more housing may house various subsystems of the light-enhance ozone wafer processing system 40. For example, the housing 80 may include the photolytic material supply system 60 and the substrate processing system 70 therein. In another embodiment, the housing 80 may include the beam control system 46, the photolytic material supply system 60, and the substrate processing system 70 therein. In yet another embodiment, the housing may include the optical radiation source 42, the photolytic material supply system 60, the substrate processing system 70, and the control system 78 therein.

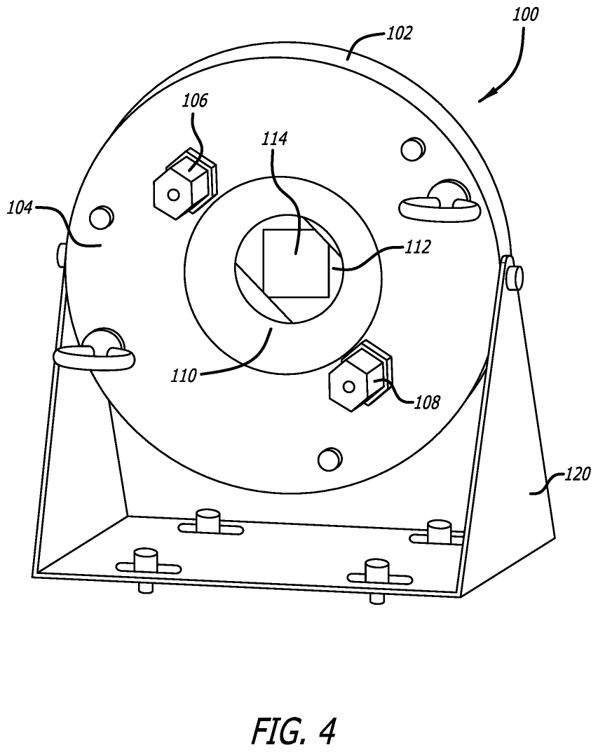

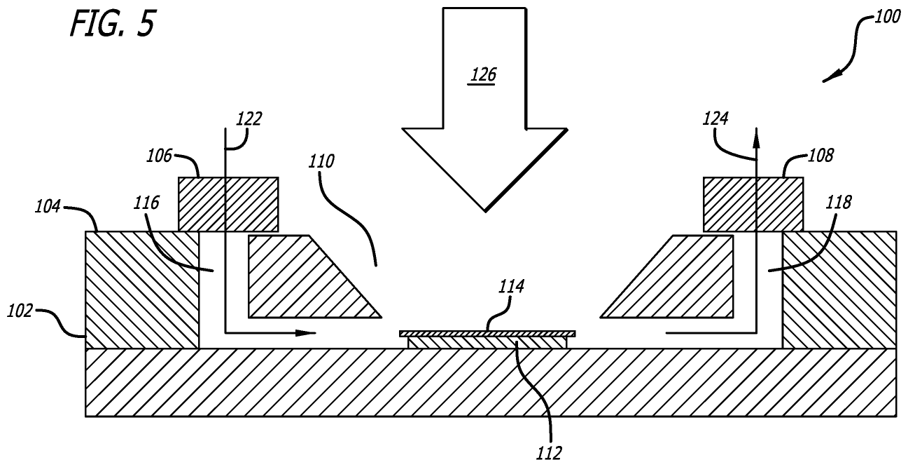

FIGS. 4 and 5 show various view of a wafer support device 100 used within various embodiment of a light-enhance ozone wafer processing system. As shown, the wafer support device 100 includes a body 102 having at least a first surface 104 formed thereon. At least one fluid inlet 106 and at least one fluid outlet 108 may be formed on the body 102. At least one recess 110 may be formed in the body 102. In one embodiment, the recess 110 is sized to receive at least one wafer, coupon, or substrate 114 therein. At least one chuck 112 may be located within the recess 110 and configured to support the wafer, coupon, or substrate 114 within the recess 110. In some embodiments, the recess 110 includes at least one window, lens, flow agitating device or feature positioned therein or otherwise formed therein (not shown) although those skilled in the art will appreciate that the recess 110 need not include such a window or flow agitating device. In one embodiment, the flow agitating device or feature may be configured to ensure that a turbulent flow of photolytic material is present. As shown in FIG. 5, at least one inlet passage 116 may be formed within the body 102 and may be in communication with the inlet 106 and the recess 110. Similarly, at least one outlet passage 118 may be formed within the body 102 and may coupled the recess 110 to the outlet 108. As such, the inlet 106 and outlet 108 may be in fluid communication with the recess 110. At least one mounting device 120 may be coupled to or formed on the body 102 thereby permitting the wafer support device 100 to be coupled to any variety of supports or devices (See FIG. 4).

Referring again to FIG. 5, during use one or more wafers, coupons or substrates 114 may be positioned on the chuck 112. Thereafter, a flow of photolytic material is introduced into recess 110 via the inlet 106. In one embodiment, the flow comprises a turbulent flow although those skilled in the art will appreciate that the flow of photolytic material 112 may be laminar. As a result, at least a portion of the wafer, coupon, or substrate 114 is subjected to or immersed within the photolytic material 112. Thereafter, the wafer, coupon, or substrate 114 subjected to or immersed within the photolytic material 112 may be subjected to optical radiation 126 resulting in the formation of optically-induced radicals having enhanced reactivity. As a result, the presence of ozone radicals fuels a chain reaction in close proximity to the photoresist on the wafer, coupon or substrate 114, which reacts with and strips photoresist molecules from the wafer surface. Thereafter, the photolytic material 124 may be evacuated from the body 102 via the outlet 108.

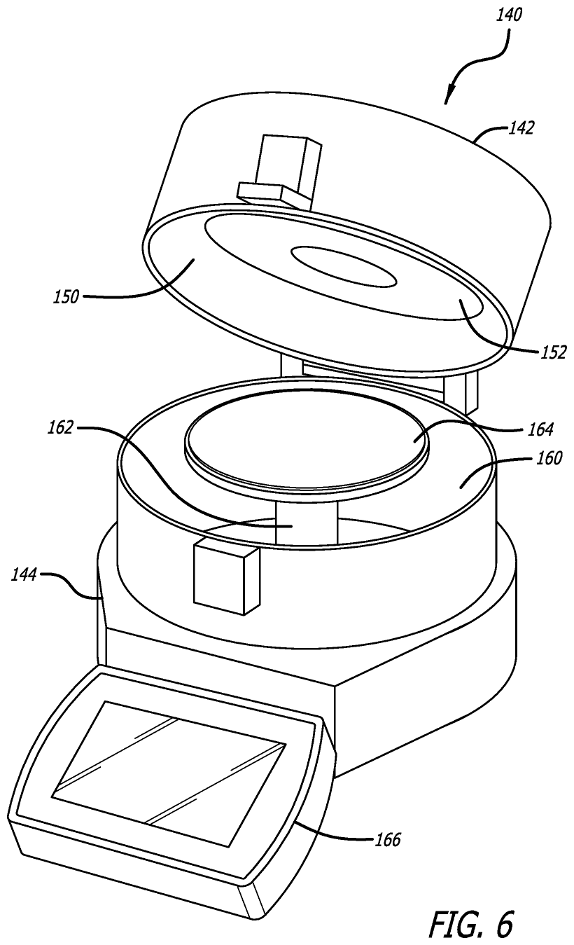

FIGS. 6-10 show various views of another embodiment of a light-enhance ozone wafer processing system. In one embodiment, the light-enhance ozone wafer processing system 140 shown in FIGS. 6-10 incorporate portions of various spin coating tools commonly used in photolithography processes. As shown, the wafer processing system 140 includes a first body 142 and at least a second body 144. The first body 142 defines at least one first body recess 150 therein. Although not shown, the first body 142 may define at least one aperture permitting optical radiation from at least one optical radiation source to traverse through the lid body 142. Optionally, the aperture may include one or more windows or lenses therein. The first body recess 150 may be sized to receive at least one dispensing system 152 therein. The second body 144 defines at least one second body recess 160 sized to receive at least one rotatable wafer chuck 162 configured to support at least one wafer 164 therein. Optionally, the wafer chuck 162 need not be rotatable. Rather, the wafer chuck 162 may be configured to move along any desired plane. At least one control system 166 may be coupled to or in communication with the various components of the light-enhance ozone wafer processing system 140.

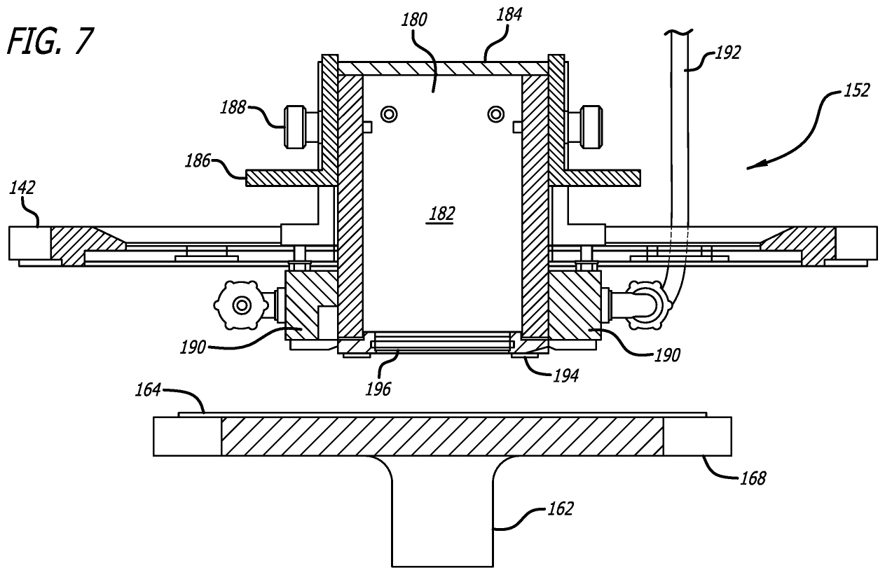

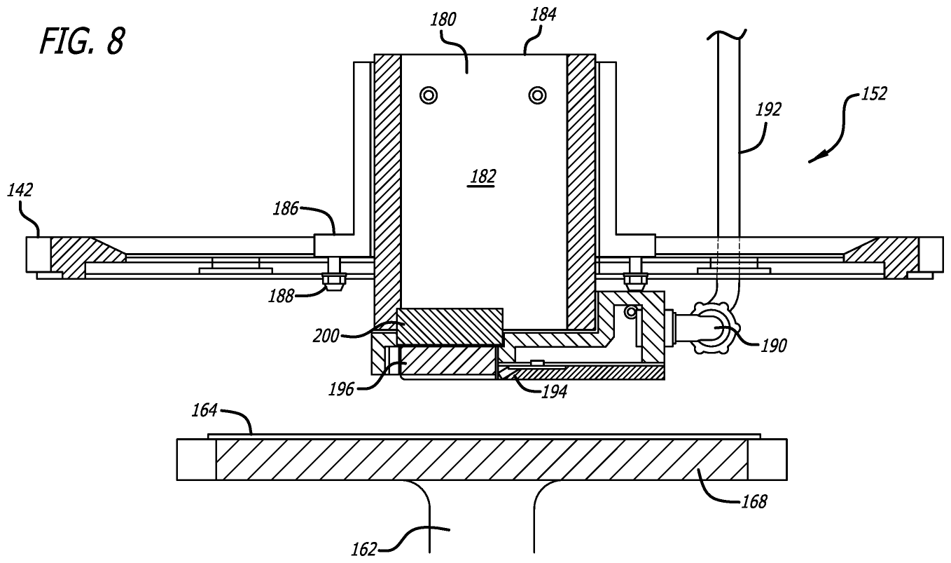

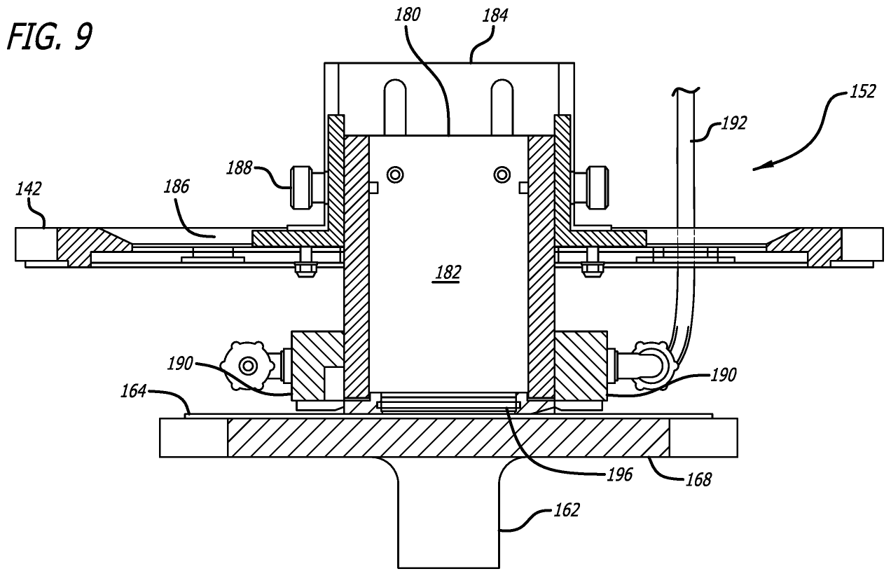

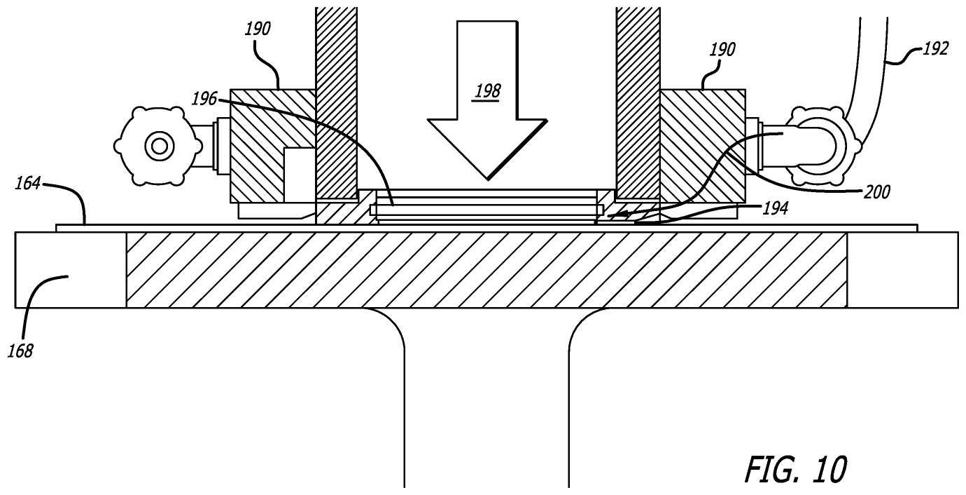

As shown in FIGS. 7-10, the dispensing system 152 includes at least one dispensing head body 180 defining at least one body receiver 182 therein. In one embodiment, the body receiver 182 is configured to permit optical radiation to traverse through the first body 142 and the head body 180, thereafter being incident on at least one wafer 164 positioned on at least one wafer chuck 162. As such, a portion of the head body 180 may traverse through the lid body 142. In another embodiment, the body receiver 182 may be sized to receive and position at least one optical radiation source (not shown) therein. For example, FIG. 8 shows an embodiment of the dispensing system 152 which utilizes an optical radiation source 200, such as a laser diode array, fiber-coupled laser device, or similar optical radiation source, positioned within the head body 180. Exemplary optical radiation sources include, without limitations, LEDs, LED arrays, lasers, laser diodes, fiber optical devices, fiber lasers, and the like. More specifically, FIG. 7 shows an embodiment of a dispensing system 152 which utilizes an external optical radiation source to provide optical radiation. In contrast, FIG. 8 shows an embodiment of a dispensing system 152 having at least one optical radiation source 200 positioned within or coupled to the head body 180. Like the previous embodiment, the optical signal 198 traversing through or generated within the body receiver 182 may have a wavelength from about 100 nm to about 1000 nm. In a more specific embodiment, the wavelength of the optical signal is from about 250 nm to about 275 nm. At least one head frame or support body 184 may coupled to at least one of the first body 142 and the head body 180. In one embodiment, the body receiver 182 may be configured to be movably coupled to the head frame 184, thereby permitting the body receiver 182 to controllably extend from and retract to the first body 142 (See FIGS. 9 and 10). As such at least one coupling feature 186 and coupler 188 may be used to couple the head body 180 to the first body 142.

Referring again to FIGS. 7-10, at least one manifold 190 may be coupled to or formed on the head body 180 and/or the body receiver 182. The manifold 190 may be configured to have one or more fluid supply conduits 192 coupled thereto, the fluid conduits 192 in fluid communication with at least one source of a photolytic material (not shown). At least one of the body receiver 182 and the manifold 190 may include at least one port or aperture formed thereon. In the embodiment shown in FIG. 10, at least one aperture 194 is formed on the dispensing head body 180. For example, those skilled in the art will appreciate that the aperture 194 could be formed on or proximate to the manifold 190. The aperture 194 is in communication with the photolytic material source (not shown) via the fluid conduit 192. Optionally, any number of apertures 194 may be formed anywhere on the dispensing head body 180.

As shown in FIGS. 6-10, at least one optical element 196 may be coupled to or retained by the body receiver 182. In one embodiment, the optical element 196 comprises a window, although those skilled in the art will appreciate that the optical element may comprises any variety of alternate devices including, without limitations, lenses, lenses systems, optical radiation sources, LEDs, LED arrays, laser diodes, fiber optic devices, sensors, cameras, light guides, and the like. For example, as shown in FIG. 8, the optical element 196 comprises one of more windows configured to output optical radiation from the optical radiation source 200 positioned within the body receiver 182. In one embodiment, the optical radiation 198 has a wavelength between about 100 nm and 1000 nm. More specifically, the wavelength may be from about 250 nm to about 275 nm. In an alternate embodiment, the optical element 196 comprises a fiber laser. In addition, the optical element 196 may include one or more features configured to form a turbulent flow of material from the aperture 194. Optionally, the dispensing head body may include one or more features or devices configured to form a turbulent flow of material from the aperture 194. Exemplary flow modifying elements include ridges, vanes, obstructions, and the like (not shown) positioned within of proximate to the apertures 194. The aperture 194 may be formed proximate to at the optical element 196 such that the optical radiation 198 emitted from the head body 180 is incident on photolytic material emitted from the aperture 194.

As shown in FIGS. 7-10, one or more wafers, coupons, or substrates 164 may be positioned on the wafer support body 168. In one embodiment, the wafer support body 168 is secured to at least one wafer chuck 162 capable of rotating the wafer 164 or otherwise moving the wafer 164 positioned on the wafer support body 168 at a desired rotation rate. Further, the dispensing head body 180 may be configured to controllable extend from the first body 142 (See FIG. 6) such that a portion of the body receiver 182 is in close proximity to the wafer 164 positioned on the wafer support body 168 and retract to the first body 142 (See FIG. 6) such that the body receiver 182 is positioned proximate to the first body 142.

With reference to FIGS. 6-10, during use, a wafer 164 may be positioned on the wafer support body 168 and the first body 142 closed such that the first body 142 is proximate to the main body 144. Thereafter, processing instructions and parameters, such a spin rate of the wafer 164, optical radiation power, processing time, etc. may be entered into the control system 166. The control system 166 may position the dispensing head body 180 proximate to the wafer 164 positioned on the wafer support body 168. At least one flow of photolytic material may be established. The photolytic material may flow through the fluid conduit 192 and manifold 190 and be deposited onto the wafer 164 via the aperture 194. The photolytic material may be dispersed across the surface of the wafer 164 due to centrifugal force or similar forces. In one embodiment, the at least one turbulent flow of photolytic material is initiated on the wafer 164, although those skilled in the art will appreciate that the flow need not be turbulent. Thereafter, optical radiation 198 may be selectively applied to at least a portion of the wafer 164. In one embodiment, the optical radiation 198 is generated by an external optical radiation source (not shown) and traverses through the body receiver 182 to the wafer 164. In an alternate embodiment, the optical radiation 198 is generated by at least one optical radiation source 200 positioned within or otherwise coupled to the body receiver 182 (See FIG. 8). Like the embodiments described above, the application of optical radiation 198 to the photolytic material results in the generation of enhanced radicals resulting in the formation of optically-induced radicals having enhanced reactivity. For example, when using ozonated deionized water or gaseous ozone as a photolytic material, the optical radiation 198 generates ozone radicals which fuel a chain reaction in close proximity to the photoresist on the wafer, coupon or substrate 164, which reacts with and strip photoresist molecules from the wafer surface. Once the wafer 164 has been processed the body receiver 182 may be positioned proximate to the lid body 142 and the wafer 164 may be removed from the system 140.

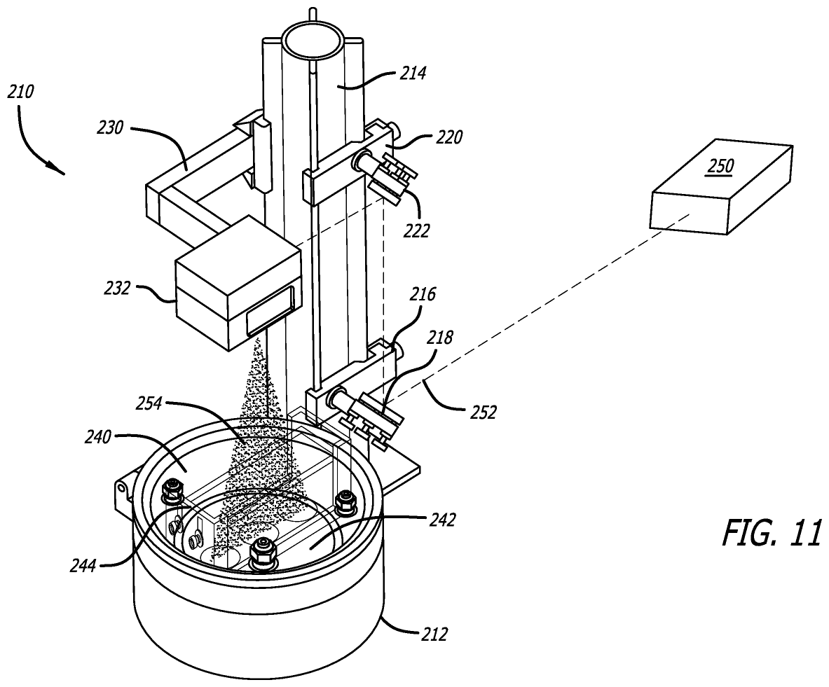

FIGS. 11-15 show alternate embodiments of the various components of a light-enhance ozone wafer processing system. As shown in FIG. 11, the light-enhance ozone wafer processing system 210 includes a processing body 212 having a coupling body or extension 214. One or more mounting devices may be coupled to the coupling body 214. In the illustrated embodiment, a first coupling mount 216 supporting a first mirror or optical element 218 and a second coupling mount 220 supporting a second mirror or optical element 222 is coupled to the coupling body 214. Optionally, any variety of device, optical elements, and the like may be coupled to the coupling body 214, including, for example, light sources, optical radiation sources, lasers, fiber optic devices, fiber lasers, diode pumped laser systems, cameras, sensors, filters, motion controllers, control systems, photolytic material sources, scanning devices, and the like. For example, in the illustrated embodiment at least one scan device or beam steering device 232 may be coupled to the coupling body 214 using at least one device mount 230. As shown, at least one of the first optical element 218, second optical element 222, and beam steering device 232 may be configured to receive optical radiation 252 from at least one optical radiation source 252 and selectively direct the optical radiation 252 to at least one work piece or substrate. In the illustrated embodiment, the optical radiation source 250 comprises an external or separate optical radiation source 250, although those skilled in the art will appreciate that the optical radiation source 250 may be coupled to pr integral with the light-enhance ozone wafer processing system 210.

Referring again to FIGS. 11-15, the processing body 212 may define at least one wafer receiver 240 configured to receive at least one wafer 242 therein. In the illustrated embodiment, at least one photolytic material dispensing system 244 (hereinafter dispenser 244) may be positioned within or proximate to the wafer receiver 240 such that the dispenser 244 is in close proximity to the wafer 242 positioned within the wafer receiver 240.

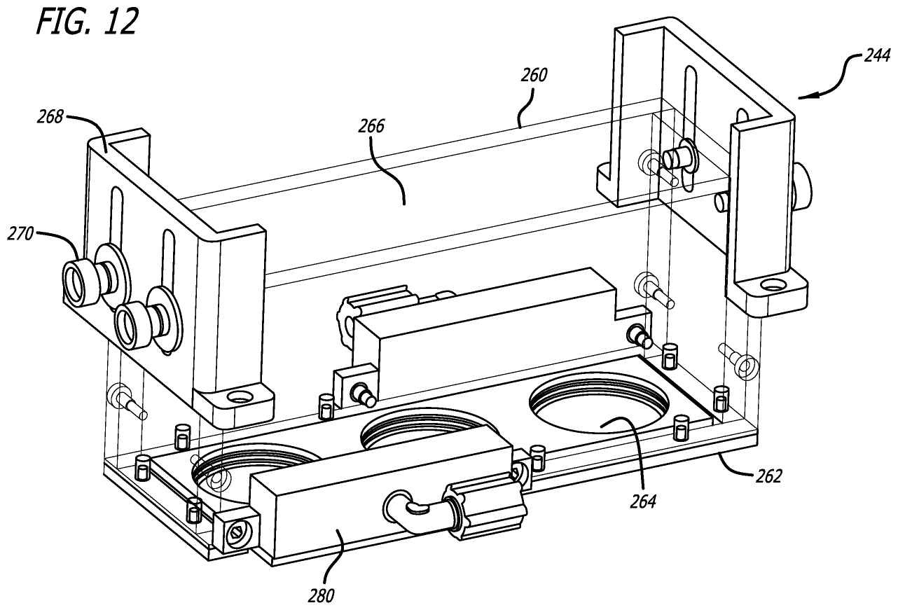

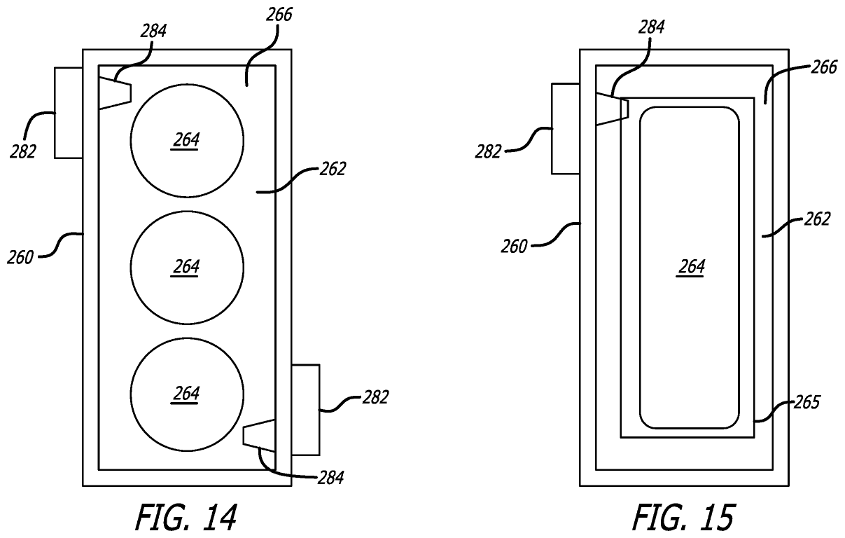

FIGS. 12-15 show various views of the dispenser 244. As shown in FIG. 12, the dispenser 244 includes a dispenser body 260 having a dispenser base 262. The dispenser body 260 and base 262 define at least one dispenser recess 266. The dispenser base 262 may include one or more apertures formed therein. For example, FIG. 12 shows an embodiment of the dispenser body 260 having multiple apertures 264 formed in the dispenser base 262. In contrast, FIG. 14 shows an embodiment of the dispenser body 260 having a single aperture 264 formed therein.

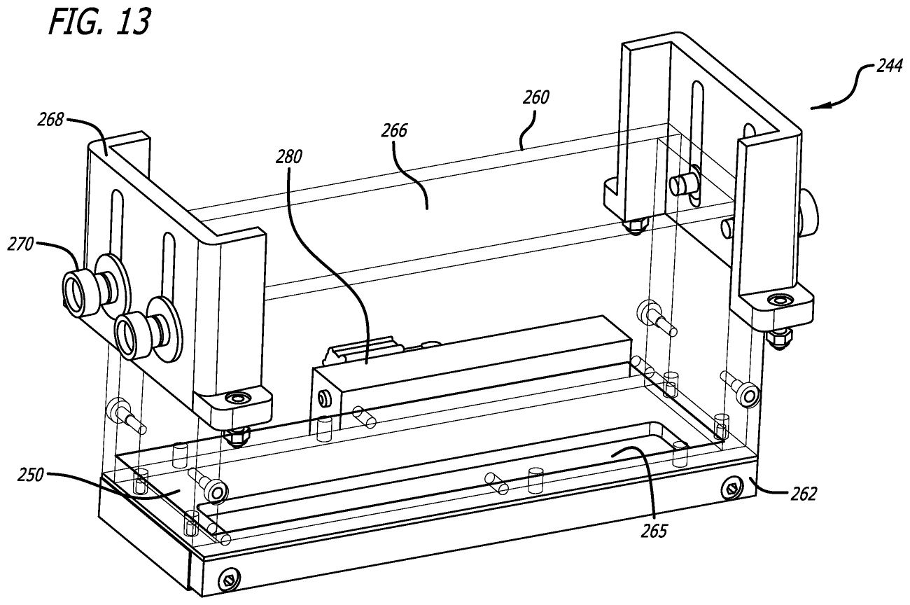

Referring again to FIGS. 12-15, the dispenser 244 may include one or more coupling extensions 268 affixed to the dispenser body 260 with one or more fasteners 270. In addition, at least one manifold 280 may be coupled to the dispenser body 260. For example, FIG. 12 shows an embodiment of a dispenser body 260 having multiple manifolds 280 affixed thereto. In contrast, FIG. 13 shows an embodiment of a dispenser body 260 having a single manifold 280 affixed thereto. The manifold 280 may be in communication with at least one photolytic material source (not shown). As shown, the manifold 280 may include a manifold body 282 having one or more manifold outlets or nozzles 284 positioned within the dispenser body recess 266. In one embodiment, the manifold outlets 284 may be configured to ensure that a turbulent flow of photolytic material is present within the dispenser body 260. Optionally, the manifold outlets 284 may be configured to ensure that a laminar flow is present within the dispenser body 260.

With reference to FIGS. 11-15, during use at least one wafer 242 is positioned within the wafer receiver 240. The wafer receiver 240 may be configured to support and rotate the wafer at a desired rotation rate. Optionally, the wafer receiver 240 need not rotate the wafer 242. Rather, the wafer receiver 240 may be configured to move the wafer 242 along any desired plane. Thereafter, the dispenser 244 may be positioned in close proximity to the wafer 242. A flow of photolytic material may be initiated within the dispenser 244. The photolytic material may be controllably applied to the wafer 242 via the at least one aperture 264 formed on the dispenser base 262. Thereafter, optical radiation from at least one optical radiation source 250 is directed to the processing body 212. For example, in FIGS. 11 and 12 show an embodiment of a light-enhance ozone wafer processing system 210 which uses an external optical radiation source 250 to emit optical radiation 252 to the first mirror 218, the second mirror 222, and the scan head 232, which cooperatively direct the optical radiation 252 to the wafer 242 positioned within the wafer receiver 240. In contrast, FIG. 13 shows an embodiment of dispenser 244 for use in a light-enhance ozone wafer processing system having at least one optical radiation source 250 therein, the optical radiation source 250 configured to emit optical radiation to the wafer 242 positioned within the wafer receiver 240. In one embodiment the optical radiation source may comprise a diode pumped solid state laser device configured to output optical radiation having a wavelength of about 100 nm to about 1000 nm. In another embodiment, the optical radiation source may comprise at least one LED device or array configured to output optical radiation having a wavelength of about 100 nm to about 1000 nm. In a more specific embodiment, the wavelength of the optical radiation is from about 250 nm to about 275 nm.

As shown in FIGS. 11 and 12, the scan head 232 may be configured to output at least one processing signal 254 directed to the processing body 212. The processing signal 254 may be directed to the wafer 242 having photolytic material applied thereto. For example, when using ozonated deionized water as a photolytic material, the optical radiation generates ozone radicals which fuel a chain reaction in close proximity to the photoresist on the wafer, coupon or substrate 242, which reacts with and strip photoresist molecules from the wafer surface. Once the wafer 242 has been processed the operation may be stopped and the wafer 242 may be removed from the system 210.

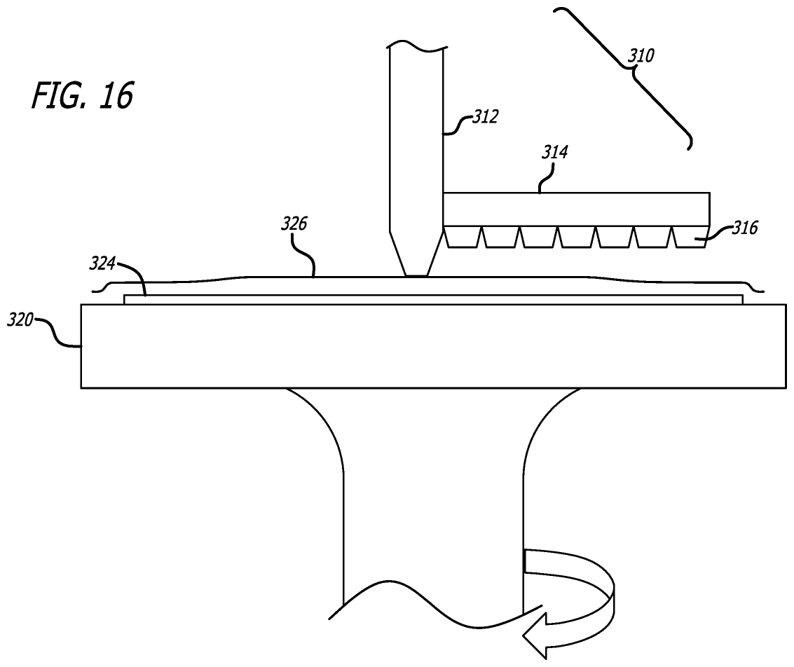

While many of the exemplary embodiments described above utilize a diode pumped solid state laser or LED array as an optical radiation source those skilled in the art will appreciate that any variety of devices could also be used as a source of optical radiation. For example, FIG. 16 shows an embodiment of processing head 310 for use in any of the embodiments described above. As shown, the processing head 310 includes photolytic material delivery device 312 having a light delivery system 314 coupled thereto or included therewith. The light delivery system 314 includes one or more individual emitters 316 thereon. Exemplary emitters include, without limitations, LEDs, led arrays, laser diodes, fiber optic devices, and the like. During use the processing head is positioned in close proximity to a wafer or substrate 324 positioned on a chuck 320. In one embodiment, the chuck 320 is configured to be controllably rotatable. Optionally, the chuck 320 may be configured to move the wafer 324 along any desired plane. At least one photolytic material 326 is dispensed from the delivery device 312 and is dispersed across the wafer 326. Thereafter, optical radiation from the light delivery system 314 may be selectively applied to the coated wafer 324. When using ozonated deionized water or gaseous ozone as a photolytic material, the optical radiation generates ozone radicals which fuel a chain reaction in close proximity to the photoresist on the wafer, coupon or substrate 324, which reacts with and strip photoresist molecules from the wafer surface.

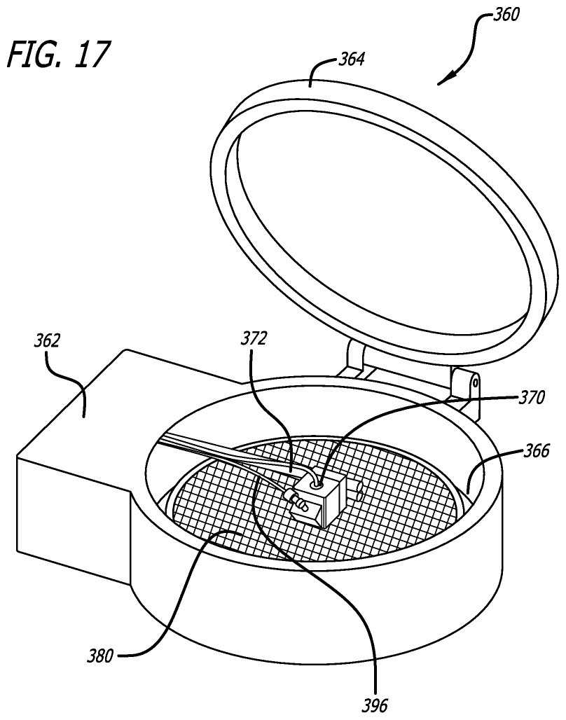

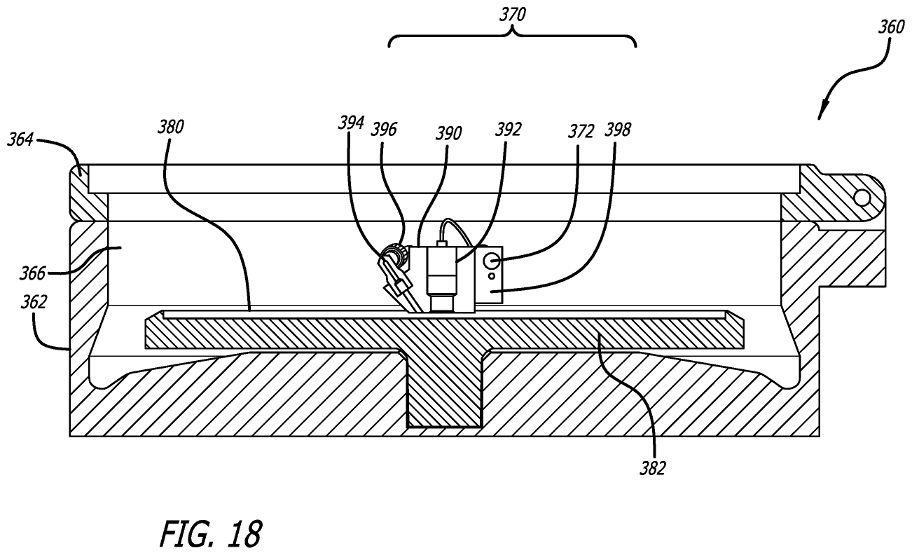

FIGS. 17 and 18 show yet another embodiment of a light-enhance ozone wafer processing system, similar to the embodiments shown in FIG. 16. As shown, the processing system 360 includes a first or lid body 364 and at least a second or main body 362. In one embodiment, the processing body 362 defines at least one processing recess 366. In the illustrated embodiment, the lid body 364 may be transparent although those skilled in the art will appreciate that the lid body 364 need not be transparent. At least one dispenser system 370 may be movable coupled to or positioned on at least one guide body 372 located within the processing recess 366. In the illustrated embodiment the dispenser system 370/guide body 372 are coupled to the processing body 362, although those skilled in the art will appreciate that at least one of the dispenser system 370 and guide body 372 may be coupled to the lid body 364.

Referring again to FIGS. 17 and 18, at least one wafer or substrate 380 may be positioned on at least one chuck 382 within the processing body 362. The dispenser system 370 may include at least one dispenser body 390 having at least one optical radiation source 392 coupled thereto or in communication therewith. Exemplary optical radiation sources include, without limitations, fiber lasers, laser diodes, laser emitters, light emitters, LEDs, and the like. Further, at least one nozzle or dispenser device 394 may be coupled to dispenser body 390. As shown, at least one conduit 396 may couple the nozzle 394 to at least one source of photolytic material (not shown). At least one drive system or motor 398 may couple the dispenser body 392 to the guide body in movable relation. Further, the dispenser system 370 may be configured to be capable of controllably extending from the lid body 364 such that the optical radiation source 392 and nozzle 394 are positioned proximate to the wafer 380 and retract from the wafer 380 to the lid body 364.

During use, at least one wafer 380 may be positioned on the chuck 382 locate within the processing body 362. Thereafter, the lid body 364 may be positioned proximate to the processing body 362. In one embodiment, the dispenser body 390 may be actuated and positioned at a desired location relative to the wafer 380 via the drive motor 398. Thereafter, one or more photolytic materials may be selectively applied to the wafer 380 via the nozzle 394 which is in communication with a photolytic material source (not show) via the conduit 396. At least a portion of the wafer 380 is coated or subjected to the with photolytic material. Thereafter, the optical radiation source 392 may be actuated to apply optical radiation to enhance the reactivity of the photolytic material applied to the coated wafer 380. When using ozonated deionized water or gaseous ozone as a photolytic material, the optical radiation generates ozone radicals which fuel a chain reaction in close proximity to the photoresist on the wafer 380, which reacts with and strip photoresist molecules from the wafer surface.

The embodiments disclosed herein are illustrative of the principles of the invention. Other modifications may be employed which are within the scope of the invention. Accordingly, the devices disclosed in the present application are not limited to that precisely as shown and described herein.

What is claimed:

1. A light-enhance wafer processing system, comprising:
a processing body having a rotatable chuck configured to support and selectively rotate at least one wafer;
at least one processing head in communication with at least one source of at least one photolytic material, the processing head configured to selectively flow the at least one photolytic material onto a surface of the at least one wafer; and
at least one optical radiation source configured to provide optical radiation to at least a portion of the at least one wafer having at least one photolytic material applied thereto, the optical radiation is configured to result in the formation of optically-induced radicals having enhanced reactivity with at least one material applied to the at least one wafer.

2. The light-enhanced wafer processing system of claim 1 wherein the at least one processing head is movable in relation to the rotatable chuck.

3. The light-enhance wafer processing system of claim 2 wherein the at least one processing head may be selective positioned proximate to the at least one wafer and selective retracted distally from the at least one wafer.

4. The light-enhance wafer processing system of claim 1 wherein the at least one processing head is configured to create at least one turbulent flow of the at least one photolytic material on a surface of the at least one wafer.

5. The light-enhance wafer processing system of claim 1 wherein the at least one processing head is configured to create at least one laminar flow of the at least one photolytic material on a surface of the at least one wafer.

6. The light-enhance wafer processing system of claim 1 wherein the at least one photolytic material comprises ozonated deionized water.

7. The light-enhance wafer processing system of claim 6 wherein the ozonated deionized water has a concentration of 30 ppm to 300 ppm.

8. The light-enhance wafer processing system of claim 1 wherein the at least one photolytic material comprises gaseous ozone.

9. The light-enhance wafer processing system of claim 8 wherein the gaseous ozone has a concentration of 10 g/m³ 600 g/m³.

10. The light-enhance wafer processing system of claim 1 wherein the at least one photolytic material comprises ozonated deionized water and gaseous ozone.

11. The light-enhance wafer processing system of claim 1 wherein the at least one optical radiation source is configured to output optical radiation having a wavelength of 200 nm to 300 nm.

12. The light-enhance wafer processing system of claim 1 wherein the at least one optical radiation source is configured to output optical radiation having a wavelength of 250 nm to 275 nm.

13. The light-enhance wafer processing system of claim 1 wherein the at least one optical radiation source is configured to output optical radiation having a power of 1 W to 30 W.

14. The light-enhance wafer processing system of claim 1 wherein the at least one optical radiation source is configured to output optical radiation having a power of 6 W to 10 W.

15. The light-enhance wafer processing system of claim 1 wherein the at least one optical radiation source comprises at least one diode pumped solid state laser configured to output optical radiation having a wavelength of 250 nm to 275 nm.

16. The light-enhance wafer processing system of claim 1 wherein the at least one optical radiation source comprises one or more laser diodes configured to output optical radiation having a wavelength of 250 nm to 275 nm.

17. The light-enhance wafer processing system of claim 1 wherein the at least one optical radiation source comprises one or more LEDs configured to output optical radiation having a wavelength of 250 nm to 275 nm.

18. The light-enhance wafer processing system of claim 1 wherein the at least one optical radiation source comprises one or more fiber lasers configured to output optical radiation having a wavelength of 250 nm to 275 nm.

19. The light-enhance wafer processing system of claim 1 further comprising at least one scan head configured to selectively directed at least a portion of the optical radiation to the at least one wafer.

20. The light-enhance wafer processing system of claim 1 wherein the optically-induced radicals having enhanced reactivity with at least one photoresist material applied to the at least one wafer.

21. A light-enhance wafer processing system, comprising:
a processing body having a rotatable chuck configured to support and selectively rotate at least one wafer;
at least one processing head having at least one dispenser body in communication with at least one source of at least one photolytic material, the at least one dispenser body configured to selectively flow at least one photolytic material onto a surface of the at least one wafer; and
at least one optical radiation source configured to provide optical radiation to at least a portion of the at least one wafer having photolytic material applied thereto, the optical radiation is configured to result in the formation of optically-induced radicals having enhanced reactivity with at least one material applied to the at least one wafer.

22. The light-enhanced wafer processing system of claim 21 wherein the at least one processing head is movable in relation to the rotatable chuck.

23. The light-enhance wafer processing system of claim 22 wherein the at least one processing head may be selective positioned proximate to the at least one wafer and selective retracted distally from the at least one wafer.

24. The light-enhanced wafer processing system of claim 21 further comprising at least one body receiver formed within the at least one dispenser body, the at least one body receiver configured to have the optical radiation propagate there through.

25. The light-enhanced wafer processing system of claim 21 further comprising at least one body receiver formed within the at least one dispenser body, the at least one body receiver configured to have the at least one optical radiation source positioned therein.

26. The light-enhance wafer processing system of claim 21 wherein the processing head is configured to create at least one turbulent flow of photolytic material on a surface of the at least one wafer.

27. The light-enhance wafer processing system of claim 21 wherein the photolytic material comprises ozonated deionized water.

28. The light-enhance wafer processing system of claim 27 wherein the ozonated deionized water has a concentration of 30 ppm to 300 ppm.

29. The light-enhance wafer processing system of claim 21 wherein the photolytic material comprises gaseous ozone.

30. The light-enhance wafer processing system of claim 29 wherein gaseous ozone has a concentration of 10 g/m³ 600 g/m³.

31. The light-enhance wafer processing system of claim 21 wherein the photolytic material comprises ozonated deionized water and gaseous ozone.

32. The light-enhance wafer processing system of claim 21 wherein the optical radiation source is configured to output optical radiation having a wavelength of 250 nm to 275 nm.

33. The light-enhance wafer processing system of claim 21 wherein the optical radiation source is configured to output optical radiation having a power of 6 W to 10 W.

34. The light-enhance wafer processing system of claim 21 wherein the optical radiation source comprises a diode pumped solid state laser configured to output optical radiation having a wavelength of 250 nm to 275 nm.

35. The light-enhance wafer processing system of claim 21 wherein the optical radiation source comprises one or more laser diodes configured to output optical radiation having a wavelength of 250 nm to 275 nm.

36. The light-enhance wafer processing system of claim 21 wherein the optical radiation source comprises one or more LEDs configured to output optical radiation having a wavelength of 250 nm to 275 nm.

37. The light-enhance wafer processing system of claim 21 wherein the optical radiation source comprises one or more fiber lasers configured to output optical radiation having a wavelength of 250 nm to 275 nm.

38. The light-enhance wafer processing system of claim 21 wherein the optical radiation source comprises one or more diode lasers configured to output optical radiation having a wavelength of 250 nm to 275 nm.

39. The light-enhance wafer processing system of claim 21 wherein the optically-induced radicals having enhanced reactivity with at least one photoresist material applied to the at least one wafer.

40. A light-enhance ozone wafer processing system, comprising:
a rotatable chuck configured to support and selectively rotate at least one wafer;
at least one dispenser body configured to selectively flow at least one photolytic material onto a surface of the at least one wafer; and
at least one optical radiation source configured to provide optical radiation to at least a portion of the at least one wafer having photolytic material applied thereto, the optical radiation is configured to result in the formation of optically-induced ozone radicals having enhanced reactivity with at least one material applied to the at least one wafer.
